(19) United States
(12) Patent Application Publication
(10) Pub. No.: US 2018/0138285 A1
(43) Pub. Date: May 17, 2018

(54) METHODS OF FORMING INTEGRATED CIRCUIT STRUCTURE WITH SILICIDE REIGON

(71) Applicant: GLOBALFOUNDRIES Inc., Grand Cayman (KY)

(72) Inventors: Clemens Christof Stefan Fitz, Dresden (DE); Vijayaragavan Varadharajan, Reutlingen (DE)

(21) Appl. No.: 15/353,771

(22) Filed: Nov. 17, 2016

(51) Int. Cl. H01L 29/66; H01L 21/285; H01L 21/683; H01L 21/67

(52) U.S. Cl. CPC H01L 29/665; H01L 21/67115; H01L 21/6831; H01L 21/28518

(57) ABSTRACT

Embodiments of the present disclosure relate to methods of forming an integrated circuit (IC) structure with a silicide region. Methods according to the present disclosure can include providing a structure including: a semiconductor region positioned on an electrostatic chuck, and a precursor metal positioned on and in contact with the semiconductor region; heating the semiconductor region of the structure to an annealing temperature by increasing a temperature of the electrostatic chuck; irradiating the structure with a radiant heat source, such that at least some of the precursor metal migrates into a portion of the semiconductor region to form a silicide region during the irradiating; and removing a remainder of the precursor metal from the structure to expose the silicide region, after the irradiating.

### BACKGROUND

### Technical Field

The present disclosure relates to methods of forming an integrated circuit (IC) structure with a silicide region therein. In particular, embodiments of the present disclosure include methods of forming an IC structure to reduce or eliminate the presence of pipe defects in a silicide region fabricated, e.g., as part of a transistor structure.

### Related Art

Each IC can be made up of billions of interconnected devices, such as transistors, resistors, capacitors, and diodes, located on one or more chips of semiconductor substrate material. The quality and viability of a product including an IC can be at least partially dependent on the techniques used for fabricating the IC and the structure of various components therein. Fabrication of an IC can include two phases: front-end-of-line processes (FEOL) and back-end-of-line processes (BEOL). FEOL generally includes fabrication processes performed on a wafer up to and including the formation of a first “metal level,” i.e., a metal wire for connecting several semiconductor devices together. In the case of a transistor, a group of vertically-extending conductive contacts can provide electrical connections to the transistor from other functional elements of a circuit. BEOL generally includes fabrication processes following the formation of the first metal level, including the formation of all subsequent metal levels. Each metal level can include metal wires therein, which can be connected to other metal levels through vertically-oriented conducting wires known as vias. In conventional BEOL processing, a layer of vias is formed to connect devices in an IC structure to a layer of metal wires formed on top of the vias, with a successive layer of vias formed thereon, followed by another layer of meal wires, etc. To provide greater scaling and sophistication of the fabricated device, the number of metal levels can be varied to suit a particular application, e.g., by providing four to six metal levels, or as many as, in a further example, sixteen or more metal levels.

Conductive contacts extending between levels, or similar structures such as vias, may be fabricated to include additional materials for providing separation between conductive metals and insulating materials in the IC structure. Both contacts and vias are referred to collectively herein by use of the terms “contact,” “metal contact,” and/or “conductive contact.” In conventional processing, such structures may be connected to portions of a transistor structure including metal-silicon compounds (“silicide”) with higher electrical conductivity than semiconductor materials (e.g., silicon). Conventional formation of silicide compounds may include depositing a meal over semiconductor material, and annealing the semiconductor material and deposited metal several times. Annealing such materials several times may, in turn, be associated with manufacturing defects such as silicide formation in non-targeted regions. Such defects may cause differences between desired and actual operation of a device. In some cases, a manufacturer may allocate additional time, materials, etc., on additional processing techniques for removing defects in a silicide region in the event that they appear.

### SUMMARY

A first aspect of the disclosure provides a method of forming an integrated circuit (IC) structure, the method including: providing a structure including: a semiconductor region positioned on an electrostatic chuck, and a precursor metal positioned on and in contact with the semiconductor region; heating the semiconductor region of the structure to an annealing temperature by increasing a temperature of the electrostatic chuck; irradiating the structure with a radiant heat source, such that at least some of the precursor metal migrates into a portion of the semiconductor region to form a silicide region during the irradiating; and removing a remainder of the precursor metal from the structure to expose the silicide region, after the irradiating.

A second aspect of the disclosure provides a method of forming an integrated circuit (IC) structure, the method including: providing a structure including: a semiconductor region positioned on an electrostatic chuck, wherein a region of engagement between the electrostatic chuck and the semiconductor region defines a first surface of the structure, and a precursor metal positioned on the semiconductor region, and including an exposed second surface positioned opposite the first surface of the structure; heating the first surface of the structure with the electrostatic chuck to raise a temperature of the semiconductor region to an annealing temperature; irradiating the second surface of the structure with a radiant heat source such that at least some of the precursor metal migrates into a portion of the semiconductor region to form a silicide region during the irradiating; removing a remainder of the precursor metal from the structure to expose the silicide region, after the irradiating; and forming an electrical contact to the silicide region without repeating the annealing and the removing.

A third aspect of the disclosure provides a method of forming an integrated circuit (IC) structure, the method including: providing a structure including: a semiconductor region positioned on an electrostatic chuck, wherein a region of engagement between the electrostatic chuck and the semiconductor region defines a first surface of the structure, and a precursor metal positioned on the semiconductor region, and including an exposed second surface positioned opposite the first surface of the structure; heating the first surface of the structure with the electrostatic chuck to raise a temperature of the semiconductor region to an annealing temperature; irradiating the second surface of the structure with a radiant heat source for a time period of between approximately 0.20 milliseconds (ms) and approximately 4.0 ms, such that at least some of the precursor metal migrates into a portion of the semiconductor region to form a silicide region during the irradiating, wherein a temperature of the radiant heat source during the irradiating is greater than the annealing temperature; removing a remainder of the precursor metal from the structure to expose the silicide region, after the irradiating; and forming an electrical contact to the silicide region without repeating the annealing and the removing, such that the silicide region is formed through a single anneal.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a conventionally-formed silicide region including a pipe defect underneath a transistor gate.

FIG. 2 shows a cross-sectional view of an initial structure according to embodiments of the present disclosure.

FIG. 3 shows a cross-sectional view of a structure being heated to an annealing temperature and irradiated according to embodiments of the present disclosure.

FIG. 4 shows a cross-sectional view of an integrated circuit (IC) structure with silicide regions formed according to embodiments of the present disclosure.

FIG. 5 shows a shows a cross-sectional view of an integrated circuit (IC) structure with silicide regions and electrical contacts thereto according to embodiments of the present disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific exemplary embodiments in which the present teachings may be practiced. These embodiments are described in sufficient detail to enable those skilled in the art to practice the present teachings and it is to be understood that other embodiments may be used and that changes may be made without departing from the scope of the present teachings. The following description is, therefore, merely exemplary.

The present disclosure relates to forming integrated circuit (IC) structures, and more specifically, processes of forming silicide regions within an IC structure to reduce or eliminate pipe defects. Methods according to the present disclosure can include forming silicide regions, e.g., self-aligned silicide regions (also known as “silicide regions”) in targeted areas of a semiconductor structure. In particular, embodiments of the disclosure include forming silicide regions by way of a single annealing process and a single irradiating process, each driven by a distinct heat source. Methods according to the present disclosure can include, e.g., providing a structure including a semiconductor region positioned on an electrostatic chuck, and a precursor metal positioned on and in contact with the semiconductor region. One surface (e.g., a lower surface) of the semiconductor region can be heated to an annealing temperature by applying heat through the electrostatic chuck. The precursor metal (positioned, e.g., on an upper surface of the semiconductor region) can be irradiated with a radiant heat source, thereby causing at least some of the precursor metal to migrate into the semiconductor region to form a silicide region during the irradiating. After the irradiating, any remaining precursor metal can be removed from the structure to expose the silicide region.

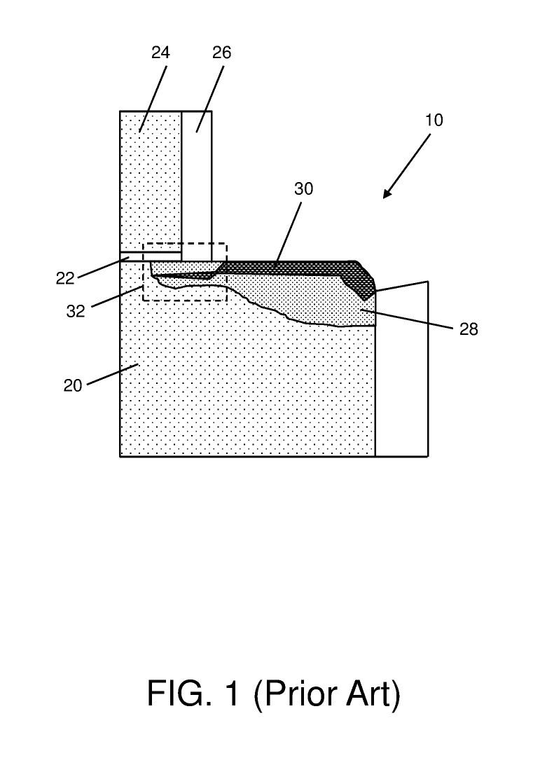

Referring to FIG. 1, a conventional IC structure 10 including, e.g., part of a transistor structure is shown to demonstrate the formation of pipe defects in conventional silicide fabrication techniques. Structure 10 may include a semiconductor region 20, on which a transistor structure, contacts, and/or other materials may be formed. Semiconductor region 20 may include e.g., silicon, germanium, silicon germanium, silicon carbide, and other materials consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other materials suitable for the composition of semiconductor region 20 can include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor region 20 may be strained. A gate dielectric 22 may be positioned on an upper surface of semiconductor region 20 to separate semiconductor region 20 from an overlying gate region 24. Gate region 24 may include one or more semiconductor materials (e.g., those referenced by example for semiconductor region 20), and/or may include one or more conductive metals. A spacer 26 can be positioned laterally adjacent to gate dielectric 22 and gate region 24 to provide lateral separation and/or electrical insulation between gate dielectric 22, gate region 24, and other structural elements.

Semiconductor region 20 may include a source/drain region 28, which may also be formed from the same material as semiconductor region 20 along with dopants for adjusting the electrical conductivity of source/drain region 28. A “dopant” material or materials introduced by “doping” generally refers to foreign materials added to a structural component to alter its electrical properties, e.g., resistivity and/or conductivity. As noted herein, conductive materials and/or semiconductive materials may include dopant compounds introduced, e.g., by any currently-known or later developed technique for introducing materials to the composition of a structure. Source/drain region 28 may define, e.g., an electrical contact, to a transistor structure which includes gate dielectric 22 and gate region 24 therein.

To provide a stronger electrical connection between source/drain region 28 and components formed thereon, a silicide region 30 may be fabricated within source/drain region 28. Silicide region 30 may generally include one or more conductive compounds including silicon and one or more conductive metals. Silicide region 30 may be formed by permitting one or more metals to react with semiconductor material in source/drain region 28, e.g., by annealing source/drain region 28 multiple times to cause diffusion of metals therein. Forming silicide region 30 through multiple and/or repeated annealing steps may form a pipe defect 32 in source/drain region 28 positioned, e.g., beneath gate region 24 and/or spacer 26. Pipe defect 32 may be positioned in source/drain region 28 away from a region where contacts to structure 10 are formed, e.g., as a result of excessive metals diffusing into source/drain region 28 underneath gate region 24 and/or spacer 26. Pipe defect 32 may impede the operation of elements formed on and/or coupled to structure 10, e.g., by providing electrical conductivity in regions where a designer may seek electrical insulation and/or reduced conductivity. In addition, pipe defect 32 of silicide region 30 may increase the risk of silicide leakage into other portions of structure 10 to impede device operation, e.g., by entering the remainder of semiconductor region 20 or insulative regions positioned near structure 10.

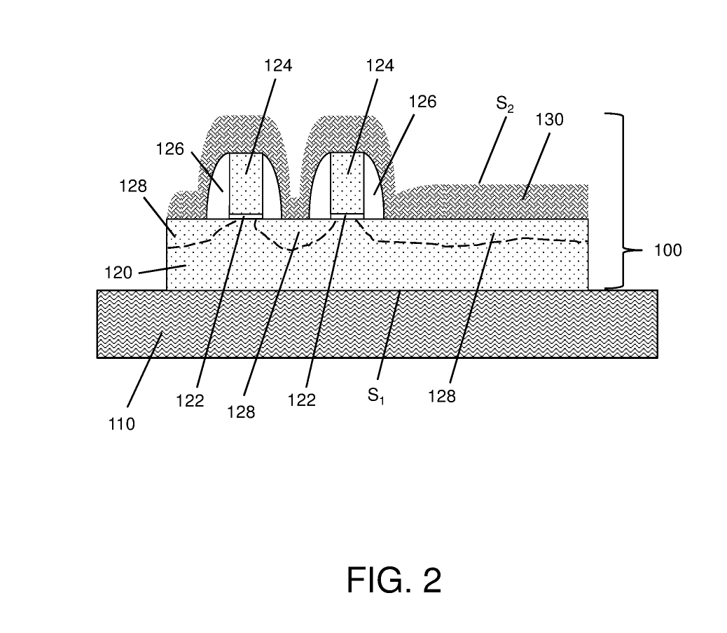

Turning to FIG. 2, an initial structure 100 for implementing methods according to the present disclosure is shown. Methods discussed herein can reduce or eliminate the formation of pipe defects 32 (FIG. 1) during the fabrication of an IC structure. In particular, embodiments of the present disclosure include forming silicide compounds within a source/drain region by applying heat from various sources and over distinct time intervals. In an embodiment, methods according to the present disclosure may include providing a structure 100 positioned on an electrostatic chuck 110, and both components may be positioned within a fabrication device (e.g., a vacuum chamber) for processing IC components. Electrostatic chuck 110 may be electrically coupled to a power source (not shown) for supplying a voltage thereto, producing a net electric charge on one surface of electrostatic chuck 110. Electrically charging electrostatic chuck 110 can allow a user to hold structure 100 in a single position relative to electrostatic chuck 110, e.g., simulating a clamping mechanism through electrostatic force. Electrostatic chuck 110 may further include one or more cooling channels (not shown) for removing heat from structure 100 as it is processed according to various embodiments. Embodiments of the present disclosure may include, e.g., mounting structure 100 on electrostatic chuck 110 before carrying out other process steps described herein.

Structure 100 can include a semiconductor region 120 positioned on electrostatic chuck 110, e.g., such that a lower surface of semiconductor region 120 defines a first surface S₁ of structure 100 contacting and overlying electrostatic chuck 110. Semiconductor region 120 may include one or more of the example compositions of semiconductor region 20 (FIG. 1) described elsewhere herein. As shown, structure 100 may further include one or more gate dielectrics 122 positioned on an upper surface of semiconductor region 120, a set of gate semiconductor regions 124 each overlying respective gate dielectric(s) 122, and spacers 126 directly laterally adjacent to gate dielectrics 122 and gate semiconductor regions 124. Gate dielectric 122 may include, without limitation, insulative materials such as hafnium silicate (HfSiO), hafnium oxide (HfO₂), zirconium silicate (ZrSiOₓ), zirconium oxide (ZrO₂), silicon oxide (SiO₂), silicon nitride (Si₃N₄), silicon oxynitride (SiON), high-k material or any combination of these materials. It is also understood that structure 100 may include a gate structure composed wholly or partially of metal compounds in alternative embodiments. Semiconductor region 120 may also include source/drain regions 128 composed of, e.g., a doped semiconductor material, where contacts to an IC element such as a transistor may be formed. In some cases, processes carried out relative to semiconductor region 120 may also be carried out on gate semiconductor region(s) 124. Thus, the processes discussed herein relative to semiconductor region 120 (e.g., forming and processing materials thereon) may also be implemented on gate semiconductor region(s) 124 except where otherwise noted specifically herein.

Structure 100 can also include a precursor metal 130 positioned on and in contact with at least semiconductor region 120 and/or gate semiconductor region(s) 124. As shown, portions of precursor metal 130 may also be formed non-selectively on portions of spacer(s) 126 and/or other exposed non-semiconductor materials of structure 100. Precursor metal 130 may include one or more metals (including, e.g., compounds and alloys) capable of migrating into semiconductor structure 120 when heated, as discussed herein. Precursor metal 130 may include, e.g., titanium (Ti), nickel (Ni), cobalt (Co), molybdenum (Mo), etc. Precursor metal 130 may be formed on semiconductor region(s) 120, 124 of structure 100, e.g., by deposition and/or one or more other processes of forming a metallic substance on an exposed surface. As used herein, the term “deposition” generally refers to any currently known or later developed technique appropriate for precursor metal 130 or other materials to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and/or evaporation. Upon being formed, an upper surface profile of precursor metal 130 may define a second surface S₂ of structure 100 positioned opposite from first surface S₁.

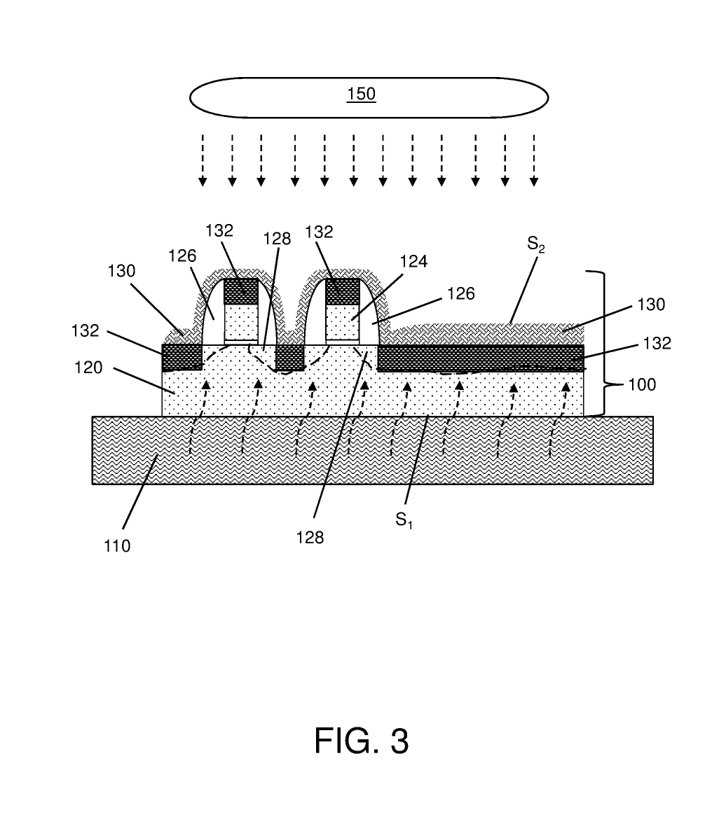

Turning to FIG. 3, the various components discussed herein may be processed to form one or more silicide regions 132 in gate semiconductor regions 124 and/or source/drain regions 128 or other portions of semiconductor region 120. The various embodiments described herein can prevent the formation of pipe defects 32 (FIG. 1) as silicide regions 132 are formed. As shown, the present disclosure can include heating semiconductor region 120 to an annealing temperature by increasing the temperature of electrostatic chuck 110. Electrostatic chuck 110 may include or otherwise be coupled to a thermal source (not shown) for raising the temperature of electrostatic chuck 110, e.g., at one or more surfaces in contact with structure 100. Electrostatic chuck 110 can thus transfer heat through first surface S₁ of structure 100, coincident with a lower surface of semiconductor region 120 (e.g., in the direction of upward-facing phantom arrows). The heating from electrostatic chuck 110 can raise the temperature of semiconductor region 120 to an annealing temperature. As discussed herein, the term “annealing temperature” refers to an elevated temperature at which material properties of semiconductor region 120 are modified in response to heat, e.g., changes to the crystallographic orientation of semiconductor region 120 are induced. In an example embodiment, the annealing temperature may be between approximately 200 degrees Celsius (° C.) and approximately 350° C.

Embodiments of the present disclosure can also include irradiating semiconductor region 120 and precursor metal 130 with a radiant heat source 150 positioned, e.g., proximal to precursor metal 130 on second surface S₂ of structure 100. Radiant heat source 150 may be provided in the form of one or more light-based heating components for processing IC materials, and as examples may include a flashlamp (e.g., one or more high-power halogen-quartz lamps) or a laser. Radiant heat source 150 can be positioned in thermal communication with second surface S₂ of structure 100, and thus may transfer heat directly to precursor metal 130. Thus, radiant heat source 150 can apply heat to structure independently from electrostatic chuck 110. However embodied, radiant heat source 150 may be operable to perform rapid thermal processing (RTP) on precursor metal 130 of structure 100. RTP is a general term which refers to a process in which the temperature of components within structure 100, e.g., semiconductor region 120 and precursor metal 130, is rapidly increased by radiant heating from radiant heat source 150. Radiant heat source 150 can have a greatly increased temperature relative to the annealing temperature of electrostatic chuck 110. According to an example, radiant heat source 150 may have a temperature of between approximately 750° C. and approximately 850° C., as compared to an annealing temperature of electrostatic chuck 110 (e.g., between 200 degrees Celsius (° C.) and approximately 350° C.).

To form silicide regions 132, radiant heat source 150 can irradiate structure 100 over a time period of between, e.g., approximately 0.20 milliseconds (ms) and approximately 4.0 ms. Thus, embodiments of the present disclosure provide a self-aligned silicide (also known as “salicide”) formation process. That is, silicide regions 132 may be formed only in areas where precursor metal 130 (which after heated by radiant heat source 150 become a metal component of silicide region(s) 132) is in direct contact with semiconductor materials hence, are self-aligned. More specifically, silicide region(s) 132 may be formed in gate semiconductor region(s) 124 and/or source/drain region(s) 128. Irradiating structure 100 with radiant heat source 150 may thus cause at least some of precursor metal 130 to migrate into underlying semiconductor materials (e.g., semiconductor gate region 124 or source/drain region(s) 128) in response to the elevated temperature. At least a portion of precursor metal 130 can enter and react with underlying semiconductor materials without migrating into non-semiconductor portions of structure 100 (e.g., gate dielectric 122 (FIG. 2) or spacers 126), e.g., due to the differences in material composition. Silicide region 132 may be include one or more compounds formed by reaction between the composition of semiconductor region 120 and precursor metal 130 while structure 100 is heated and irradiated. In an example, silicide region 132 may include nickel silicide (NiSi) when precursor metal 130 includes nickel (Ni). In other embodiments, silicide region 132 may include, e.g., cobalt silicide (CoSi₂), titanium silicide (TiSi₂), tungsten silicide (WSi₂), tantalum silicide (TaSi₂), platinum silicide (PtSi₂), etc., each of which may be formed at different temperatures and with varying amounts of electrical conductivity.

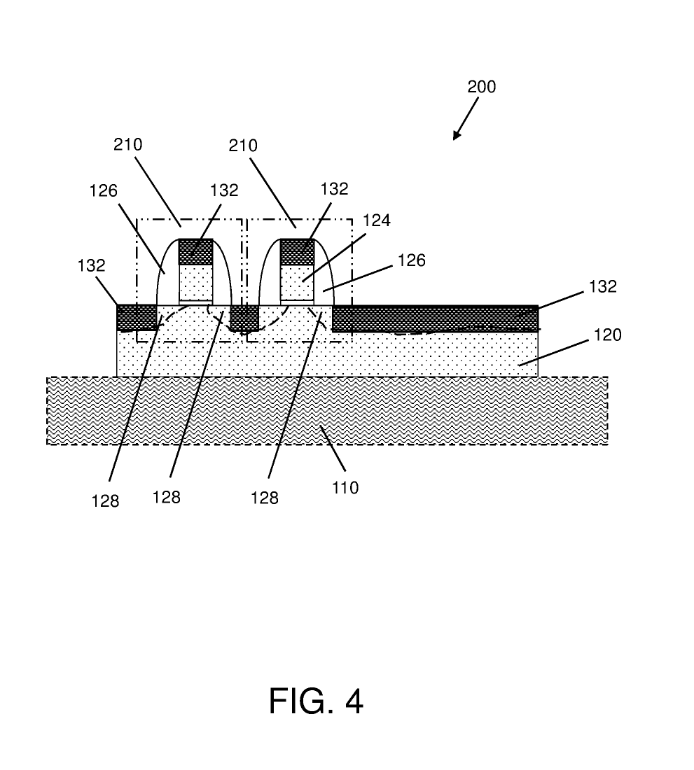

Turning to FIG. 4, embodiments of the present disclosure can include removing precursor metal 130 from semiconductor region 120 without removing underlying portions of silicide region(s) 132, semiconductor region 120, gate semiconductor regions 124, etc. Remaining portions of precursor metal 130 may be removed to expose underlying silicide region(s) 132, e.g., by etching precursor metal 130. “Etching” generally refers to the removal of material from a substrate (or structures formed on the substrate), and is often performed with a mask in place so that material may selectively be removed from certain areas of the substrate, while leaving the material unaffected, in other areas of the substrate. There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g. silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases which approach the wafer approximately from one direction, and therefore this process is highly anisotropic. Reactive-ion etching (RIE) operates under conditions intermediate between sputter and plasma etching and may be used to produce deep, narrow features, such as shallow isolation trenches (SIT). In any event, precursor metal 130 may be removed to expose silicide region 132 previously formed previously by the single annealing and irradiating steps described herein.

Removing precursor metal 130 can yield an IC structure 200 which includes one or more silicide regions 132. As shown, IC structure 200 can include one or more transistor structures 210 each having respective terminals where contacts to transistor structures 210 may be formed. Silicide region(s) 132 formed within gate semiconductor region(s) 124 may serve as a gate contact to a respective transistor structure 210. Silicide region(s) 132 formed within source/drain region(s) 128 of semiconductor region 120 may serve as a source or drain contact to transistor structure 210. Structure 200 may remain mounted on electrostatic chuck 110 (shown in phantom) after silicide regions 132 are formed, and/or may be unmounted from electrostatic chuck 110 in subsequent processes. Further processing of structure 200 may occur without repeating the heating or irradiating processes described elsewhere herein. Thus, semiconductor region 120 and precursor metal 130 may be subjected to a single heating and irradiating to form silicide region(s) 132, instead of multiple heating and/or irradiating processes. Implementing a single heating and irradiating to form silicide region(s) 132 pursuant to embodiments of the present disclosure can prevent or reduce the formation of pipe defects 32 (FIG. 1) discussed elsewhere herein.

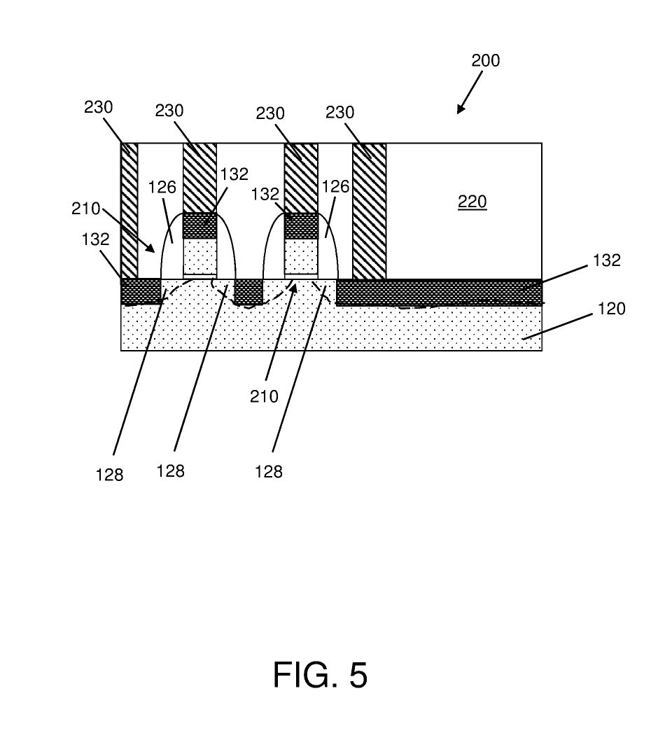

Turning to FIG. 5, structure 200 is shown with components which electrically connect transistor structures 210 to other materials. After silicide region(s) 132 are formed, structure 200 can be removed from electrostatic chuck 110. An insulator 220 may be formed over silicide region(s) 132, transistor structures 210, and other exposed surfaces, e.g., by deposition. Insulator 220 may include the same or similar materials used to form spacer(s) 126 of transistor structures 210, or may include different materials. Materials appropriate for the composition of insulator 220 may include, for example, silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, SiLK (a polyarylene ether available from Dow Chemical Corporation), a spin-on silicon-carbon containing polymer material available from JSR Corporation, other low dielectric constant (<3.9) material, or layers thereof.

After insulator 220 is formed, portions of insulator 220 can be covered by a masking material to define one or more locations for creating contacts to transistor structure(s) 210. The portions of insulator 220 not covered by such masking materials can then be removed (e.g., by etching), and a set of contacts 230 may be formed therein. Contacts 230 can include one or more conductive metals for providing an electrical connection between components of an IC structure, and may include, e.g., copper (Cu), aluminum (Al), tungsten (W), etc. Contacts 230 may also include, e.g., a refractory metal liner (not shown) positioned directly laterally adjacent to insulator 220, and such liners may be formed from, e.g., titanium nitride (TiN), tantalum nitride (TaN), tantalum (Ta), and/or titanium (Ti) as known in the art. Contacts 230 may be formed to silicide region(s) 132, thereby electrically coupling elements of structure 200 to other IC components through contact(s) 230.

The method as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A method of forming an integrated circuit (IC) structure, the method comprising:
providing a structure including:
a semiconductor region positioned on an electrostatic chuck, the semiconductor region including a source/drain region,
a gate structure including a gate semiconductor region positioned over the semiconductor region, and
a precursor metal positioned on and in contact with the source/drain region of the semiconductor region and the gate semiconductor region of the gate structure;
heating the semiconductor region of the structure to an annealing temperature by increasing a temperature of the electrostatic chuck;
irradiating the structure with a radiant heat source, such that at least some of the precursor metal migrates into the source/drain region and the gate semiconductor region to form a source/drain silicide region and a gate silicide region during the irradiating, while maintaining the annealing temperature at the semiconductor region with the electrostatic chuck; and
removing a remainder of the precursor metal from the structure to expose the source/drain silicide region and the gate silicide region, after the irradiating.

2. The method of claim 1, further comprising mounting the semiconductor region on the electrostatic chuck before the heating of the semiconductor region.

3. The method of claim 2, wherein the heating includes heating the electrostatic chuck to an initial temperature below a temperature of the radiant heat source, before irradiating the precursor metal with the radiant heat source.

4. The method of claim 3, wherein the initial temperature is between approximately 200 degrees Celsius (° C.) and approximately 350° C.

5. The method of claim 3, wherein the temperature of the radiant heat source is between approximately 750° C. and approximately 850° C.

6. The method of claim 1, wherein the radiant heat source comprises one of a flashlamp or a laser.

7. The method of claim 1, wherein the irradiating includes exposing the precursor metal to the radiant heat source for a time period of between approximately 0.20 milliseconds (ms) and approximately 4.0 ms.

8. The method of claim 1, wherein the precursor metal includes nickel, and wherein the silicide region includes a nickel silicide (NiSi).

9. The method of claim 1, further comprising forming an electrical contact to the silicide region without repeating the heating or the removing.

10. (canceled)

11. A method of forming an integrated circuit (IC) structure, the method comprising:
providing a structure including:
a semiconductor region positioned on an electrostatic chuck, the semiconductor region including a source/drain region, wherein a region of engagement between the electrostatic chuck and the semiconductor region defines a first surface of the structure,
a gate structure including a gate semiconductor region positioned over the semiconductor region, and
a precursor metal positioned on the source/drain region of the semiconductor region and the gate semiconductor region of the gate structure, and including an exposed second surface positioned opposite the first surface of the structure;
heating the first surface of the structure with the electrostatic chuck to raise a temperature of the semiconductor region to an annealing temperature;
irradiating the second surface of the structure with a radiant heat source such that at least some of the precursor metal migrates into the source/drain region and the gate semiconductor region to form a source/drain silicide region and a gate silicide region during the irradiating, wherein the irradiating includes continuing the heating of the first surface of the structure with the electrostatic chuck to maintain the annealing temperature at the first surface of the structure;
removing a remainder of the precursor metal from the structure to expose the source/drain silicide region and the gate silicide region, after the irradiating; and
forming an electrical contact to the silicide region without repeating the annealing and the removing.

12. (canceled)

13. The method of claim 11, wherein the temperature of the electrostatic chuck is between approximately 200 degrees Celsius (° C.) and approximately 350° C. during the heating.

14. The method of claim 11, wherein the radiant heat source comprises one of a flashlamp or a laser.

15. The method of claim 11, wherein the irradiating includes exposing the precursor metal to the radiant heat source for a time period of between approximately 0.20 milliseconds (ms) and approximately 4.0 ms.

16. The method of claim 11, wherein the precursor metal includes nickel, and wherein the silicide region includes a nickel silicide (NiSi).

17. The method of claim 11, a temperature of the radiant heat source during the irradiating is between approximately 750° C. and approximately 850° C.

18. (canceled)

19. A method of forming an integrated circuit (IC) structure, the method comprising:
providing a structure including:
a semiconductor region positioned on an electrostatic chuck, wherein a region of engagement between the electrostatic chuck and the semiconductor region defines a first surface of the structure, and
a precursor metal positioned on the semiconductor region, and including an exposed second surface positioned opposite the first surface of the structure;
heating the first surface of the structure with the electrostatic chuck to raise a temperature of the semiconductor region to an annealing temperature;
irradiating the second surface of the structure with a radiant heat source for a time period of between approximately 0.20 milliseconds (ms) and approximately 4.0 ms, such that at least some of the precursor metal migrates into a portion of the semiconductor region to form a silicide region during the irradiating, wherein a temperature of the radiant heat source during the irradiating is greater than the annealing temperature, and wherein the irradiating includes maintaining the heating of the first surface of the structure with the electrostatic chuck during the irradiating;
removing a remainder of the precursor metal from the structure to expose the silicide region, after the irradiating; and
forming an electrical contact to the silicide region without repeating the annealing and the removing, such that the silicide region is formed through a single anneal.

20. The method of claim 19, wherein the semiconductor region comprises a transistor source/drain region, and wherein the transistor source/drain region is positioned adjacent to a transistor gate.

21. The method of claim 1, wherein the silicide region is formed from a single implementing of the heating and the irradiating, and wherein the silicide region is free of pipe defects after the single implementing of the heating and the irradiating.
